(19) United States
(12) Patent Application Publication
(10) Pub. No.: US 2025/0286348 A1
(43) Pub. Date: Sep. 11, 2025

(54) Degenerate Distributed Feedback Lasers

(71) Applicant: The Regents of the University of California, Oakland, CA (US)

(72) Inventors: Filippo CAPOLINO, Irvine, CA (US); Tarek Khedr Abdalla MEALY, San Diego, CA (US); Albert Herrero PARAREDA, Irvine, CA (US); Nathaniel FURMAN, Irvine, CA (US)

(21) Appl. No.: 18/657,723

(22) Filed: May 7, 2024

Related U.S. Application Data
(60) Provisional application No. 63/464,717, filed on May 8, 2023.

(51) Int. Cl. H01S 5/12; H01S 5/0225; H01S 5/10

(52) U.S. Cl. CPC H01S 5/12; H01S 5/0225; H01S 5/1003

(57) ABSTRACT

Degenerate distributed feedback lasers utilizing DBE-supporting waveguides are provided. In one embodiments, a degenerate distributed feedback laser (DDFB) is provided, the DDFB laser comprising: a pump source operatively connected to a gain system, wherein the pump source provides power to a gain system; the gain system operatively connected to at least one DBE-supporting waveguide, wherein the gain system stimulates emission and amplification for lasing; at least one DBE-supporting waveguide that supports four degenerate modes and a degenerated feedback; and a coupler operatively connected to the at least one DBE-supporting waveguide, wherein the coupler collects and focuses light from the DBE-supporting waveguide and outputs a laser beam.

### CROSS-REFERENCE TO RELATED APPLICATION

The current application claims priority to U.S. Provisional Patent Application No. 63/464,717, filed on May 8, 2023, the disclosure of which is incorporated herein by reference.

### FEDERAL FUNDING SUPPORT

This invention was made with Government support under Grant No. FA9550-18-1-0355, awarded by the Air Force Office of Scientific Research and Grant No. ECCS-1711975, awarded by the National Science Foundation. The Government has certain rights in the invention.

### FIELD OF THE INVENTION

The present invention generally relates to optics and more specifically to optical devices based on modal degeneracy conditions.

### BACKGROUND

Optical communications or optical telecommunications may be described as communication using light to carry information. Typically, an optical communication system may use a transmitter, which may encode a message (e.g., information) into an optical signal, a channel, which may carry the signal to its destination, and a receiver, which may reproduce the message from the received optical signal. Optical communication systems may utilize optical fibers, optical amplifiers, lasers, switches, routers, and other related technologies.

### SUMMARY OF THE INVENTION

The various embodiments of the present degenerate distributed feedback (DDFB) lasers contain several features, no single one of which is solely responsible for their desirable attributes. Without limiting the scope of the present embodiments, their more prominent features will now be discussed below. After considering this discussion, and particularly after reading the section entitled “Detailed Description,” one will understand how the features of the present embodiments provide the advantages described here.

In a first aspect, a DDFB laser is provided, the DDFB laser comprising: a pump source operatively connected to a gain system, wherein the pump source provides power to a gain system; the gain system operatively connected to at least one DBE-supporting waveguide, wherein the gain system stimulates emission and amplification for lasing; at least one DBE-supporting waveguide that supports four degenerate modes and a degenerated feedback; and a coupler operatively connected to the at least one DBE-supporting waveguide, wherein the coupler collects and focuses light from the DBE-supporting waveguide and outputs a laser beam.

In an embodiment of the first aspect, the at least one DBE-supporting waveguide comprises a first waveguide and a second waveguide, wherein the first and second waveguides are coupled.

In another embodiment of the first aspect, the first waveguide comprises a plurality of first optical gratings, and wherein each of the plurality of first optical gratings are separated by an equal distance.

In another embodiment of the first aspect, the plurality of first optical gratings are equally sized rectangular gratings.

In another embodiment of the first aspect, the second waveguide comprises a plurality of second optical gratings, and wherein each of the plurality of second optical gratings are separated by an equal distance.

In another embodiment of the first aspect, the plurality of second optical gratings are equally sized rectangular gratings.

In another embodiment of the first aspect, the plurality of first optical gratings and the plurality of second optical gratings are positioned between the first and second waveguides.

In another embodiment of the first aspect, the plurality of first optical gratings and the plurality of second optical gratings are shifted by a translation s.

In another embodiment of the first aspect, the plurality of first optical gratings and the plurality of second optical gratings are faced a same direction.

In another embodiment of the first aspect, the plurality of first optical gratings and the plurality of second optical gratings are shifted by a translation s.

In another embodiment of the first aspect, the plurality of first optical gratings and the plurality of second optical gratings are facing away from a center located between the first and second waveguides.

In another embodiment of the first aspect, the plurality of first optical gratings and the plurality of second optical gratings are shifted by a translation s.

In another embodiment of the first aspect, the second waveguide comprises a plurality of second optical gratings, and wherein each of the plurality of second optical gratings are separated by an equal distance.

In another embodiment of the first aspect, the plurality of second optical gratings are equally sized rectangular gratings.

In another embodiment of the first aspect, the plurality of second optical gratings are positioned between the first and second waveguides.

In another embodiment of the first aspect, the plurality of second optical gratings are facing away from the first and second waveguides.

In another embodiment of the first aspect, the first waveguide comprises a plurality of first holes, and wherein each of the plurality of first holes is equally sized and separated by an equal distance.

In another embodiment of the first aspect, the second waveguide comprises a plurality of holes, and wherein each of the plurality of second holes is equally sized and separated by an equal distance.

In another embodiment of the first aspect, the plurality of first holes and the plurality of second holes are shifted by a translation s.

In another embodiment of the first aspect, the second waveguide comprises a plurality of holes and wherein each of the plurality of second holes is equally sized and separated by an equal distance.

In another embodiment of the first aspect, the at least one DBE-supporting waveguide comprises a plurality of optical gratings located on a first side and a plurality of optical gratings located on a second side, and wherein: the plurality of optical gratings located on the first side and the plurality of optical gratings located on the second side are facing away from a center of the DBE-supporting waveguide; and the plurality of optical gratings located on the first side and the plurality of optical gratings located on the second side are shifted by a translation s.

### BRIEF DESCRIPTION OF THE DRAWINGS

The various embodiments of the present DDFB lasers now will be discussed in detail with an emphasis on highlighting the advantageous features. These embodiments depict the novel and non-obvious features of DDFB lasers shown in the accompanying drawings, which are for illustrative purposes only. These drawings include the following figures:

FIG. 1 is a diagram illustrating a DDFB photonic structure with double grating and broken mirror symmetry supporting guided longitudinal modes in accordance with an embodiment of the invention.

FIG. 2 is a dispersion diagram of the longitudinal modes in a DDFB double grating optimized to exhibit a degenerate band edge (DBE) and a regular band edge (RBE), where the DBE has a flatter band edge than the RBE since the DBE is formed by a degeneracy of four modes in accordance with an embodiment of the invention.

FIG. 3 is a diagram illustrating a quality factor and its fitting N⁵ scaling law of the DDFB double grating versus number of unit cells N in accordance with an embodiment of the invention.

FIG. 4 is a diagram illustrating a lasing threshold aₜₕ and its fitting N⁻⁵ scaling law of the DDFB double grating versus number of unit cells N in accordance with an embodiment of the invention.

FIGS. 5A-B are diagrams illustrating DDFB geometries with holes in accordance with an embodiment of the invention.

FIGS. 6A-B are diagrams illustrating DDFB geometries with single gratings in accordance with an embodiment of the invention.

FIGS. 7A-D are diagrams illustrating DDFB geometries with double gratings in accordance with an embodiment of the invention.

FIG. 8 is a block diagram illustrating an example DDFB laser in accordance with an embodiment of the invention.

FIG. 9 is a block diagram illustrating an example DDFB stack with an active layer and DBE-supporting waveguide that may be realized in various configurations (e.g., schematized in FIGS. 10-11) in accordance with an embodiment of the invention.

FIG. 10 is a block diagram illustrating an example DDFB stack with an active layer and DBE-supporting waveguide having two gratings on top of each other and coupled in a coupling region in accordance with an embodiment of the invention.

FIG. 11 is a block diagram illustrating an DDFB stack with an active layer and DBE-supporting waveguide having two gratings next to each other in accordance with an embodiment of the invention.

### DETAILED DESCRIPTION OF THE DRAWINGS

The following detailed description describes the present embodiments with reference to the drawings. In the drawings, reference numbers label elements of the present embodiments. These reference numbers are reproduced below in connection with the discussion of the corresponding drawing features.

One aspect of the invention includes the realization that lasers are essential components in modern optical communication systems, sensing, and others. Further, conventional distributed feedback (DFB) lasers are a type of laser diode widely used in these applications due to their stable single-frequency lasing mode operation and narrow linewidth. The DFB laser relies on a distributed feedback mechanism, where the two counterpropagating optical waves are coupled via a longitudinal grating (i.e., a corrugated structure along the direction of propagation of the guided waves) in the material. While the DFB mechanism provides a stronger frequency selectivity than conventional Fabry-Perot cavities, it tends to provide two lasing frequencies associated with both sides of the bandgap, which are sensitive to perturbations in the boundary conditions of the structure. Usually, a defect is included in the cavity to provide more stability. The DFB laser also requires introducing antireflective coatings on the sides of the DFB structure to suppress the Fabry-Perot modes in the cavity and avoid multi-mode lasing. Furthermore, putting a mirror on one side of the DFB structure and an antireflective coating on the other side may create an unbalanced situation that would cause another frequency shift with respect to the balanced situation. Furthermore, lasers with narrower linewidth than those provided by commercial DFB lasers are desired to improve laser performance in telecommunications, spectroscopy, etc. Affordable DFB lasers with high performance are therefore challenging to produce due to the costly and complex fabrication processes of high-end laser diodes required for single-mode operation. To enhance the performance of DFB lasers, the present embodiments provide degenerate DFB (DDFB) lasers.

Another aspect of the invention including the realization that DDFB lasers may provide advantages over conventional DFB lasers due to the synchronized oscillation of the four degenerate waveguide modes, including, but not limited to, reduced lasing threshold, improved power efficiency, increased mode selectivity, and an enhanced ability to operate coherently with a single frequency, as further described below. In addition, cavities based on the DDFB mechanism display a strong field amplitude enhancement away from the cavities edge, thereby reducing the optical leaking present at the end facets of conventional DFB lasers.

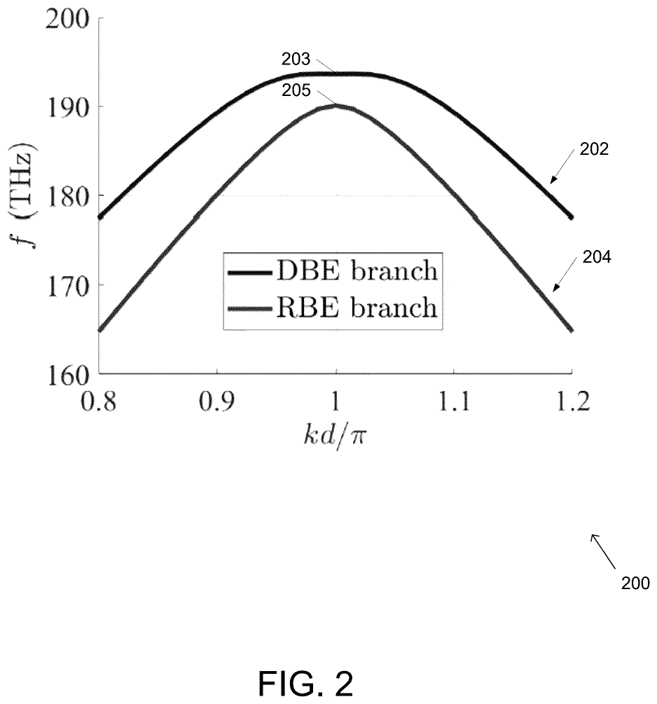

Turning now to the drawings, DDFB lasers are provided. Based on a double grating photonic structure, as further described below, DDFB lasers may operate with a single-frequency lasing mode and produce a continuous wave output with a stable wavelength; similar to traditional DFB lasers. However, the DDFB mechanism may achieve a single-frequency lasing mode operation through a degeneracy among four different Bloch eigenmodes that may form a very flat dispersion diagram (whereas a DFB laser generally uses two modes in the longitudinal grating). This regime, which is associated with the formation of a degenerate band edge (DBE) in the Bloch dispersion relation of the waveguide, is characterized by vanishing group velocity, a very flat dispersion diagram as in FIG. 2, and enhanced field amplitude in the waveguiding medium. The DBE is a fourth-order exceptional point of degeneracy (EPD). EPDs are points in the parameter space of a system where the eigenvalues and eigenvectors collapse, or coalesce, on each other. EPDs in photonic systems can exist in the presence of gain and loss, as for example in PT-symmetric systems and in lossless and gainless waveguides. However, EPDs can be formed also in multimode waveguide systems without loss and gain. The DDFB mechanisms discussed herein may be based on an EPD belonging to this latter class, i.e., a fourth-order EPD in a waveguide without loss and gain, called the DBE.

In many embodiments, the modal dispersion relation of the optical modes in a lossless and gainless double grating waveguide may be engineered to exhibit a DBE by selecting its geometric parameters. When operating at a resonance near the DBE frequency, the waves in the waveguide experience a large group delay, which increases as the fifth power of the waveguide length leading to an exceptional enhancement of the interaction between the wave and the gain medium. As a result, as shown in the theoretical calculations based on ideal coupled mode theory, DBE lasers may show single-mode oscillation even for above-threshold gain. Moreover, photon lifetime may be related to the losses in the cavity (internal and external), and to its group velocity. Therefore, the addition of the DBE fourth-order degeneracy to the DFB mechanism may result in a larger photon lifetime, thus contributing to a reduction in the lasing threshold. The present embodiments show that the degenerate mode in an active DDFB waveguide displays a remarkably low lasing threshold that ideally scales as the inverse fifth power of the waveguide length when losses are not present inside the cavity and power can escape the cavity only at its ends. In some embodiments, gain may be provided to the active medium using various methods including, but not limited to, electric pumping, also known as current injection. This technique involves supplying carriers to a doped active area, where they emit photons at the lasing frequency upon carrier recombination. In some embodiments, the current may be injected to the active area by connecting a direct-current power supply to an electrode at the top of the integrated laser (may also be referred to herein as the “front electrode”). In various embodiments, at the bottom of the device there may be another electrode (may also be referred to herein as the “rear electrode”), which serves as the electric ground. The carriers may be transported from the front electrode to the active area through the electron transport layer (ETL), made of a material with efficient electron transport properties, such as, but not limited to, ZnO, etc. This approach is commonly used to add gain in DFB lasers, even though there are alternative means of providing gain to the cavity, including, but not limited to, rare-earth material doping and the use of quantum wells. In addition, the present embodiments may include surrounding the waveguide and the active area with narrow isolation trenches away from the last unit cells to prevent current leakage.

As further described below, the present embodiments implement and verify the DBE through full-wave simulations in practical double grating photonic structures, combining the DFB mechanism with the degenerate mode arising from the coalescence of four modes. In addition, the present embodiments include various structures that are capable of supporting a DBE, such as, but not limited to two coupled periodic waveguides with holes, or two ridge waveguides with gratings, either on top of each other or next to each other. In the discussion that follows, the present embodiments may be explained utilizing gratings instead of holes because gratings may be preferable from a fabrication point of view and because wave propagation in gratings may be more conceptually accessible. Moreover, the emphasis is on showcasing the features of the DDFB mechanism rather than the specific implementation chosen for this purpose. However, holes can also provide the wave reflection needed for the formation of the DDFB mechanism. The resulting DDFB lasers may be extremely frequency selective and have a more stable resonant frequency with respect to variations of the parameters and the terminations at the sides of the cavity than DFB lasers. Therefore, in various embodiments, DDFB lasers may not require the introduction of defects within the cavity, and it shall provide a narrower line width and less noisy output than DFB lasers. The wavenumber of the degenerate mode associated with the DBE displays an exceptional sensitivity to parameter perturbations, but not its frequency of oscillation as demonstrated by the very flat dispersion diagram of the DBE in FIG. 2. While the inclusion of gain in the DDFB waveguide may perturb its modal dispersion diagram and prevent the complete formation of the DBE, DDFB lasers typically require such a small amount of gain per unit cell that in practice the distorted optical modes retain similar characteristics as those exhibited by the ideal degenerate mode. In several embodiments, this singular sensitivity provided by the DBE may actually be advantageous, since as the DDFB laser is expected to be more responsive to current modulations than the DFB laser. Consequently, DDFB lasers show promise in optical telecommunications. The results provided below show a fifth power scaling of the quality factor (which is linearly related to the group delay) with waveguide length, and an inverse fifth power scaling of the lasing threshold with waveguide length. DBE-supporting waveguides (i.e., waveguides that allow for DDFB mechanisms) in accordance with embodiments of the invention are discussed further below.

### DBE-Supporting Waveguides

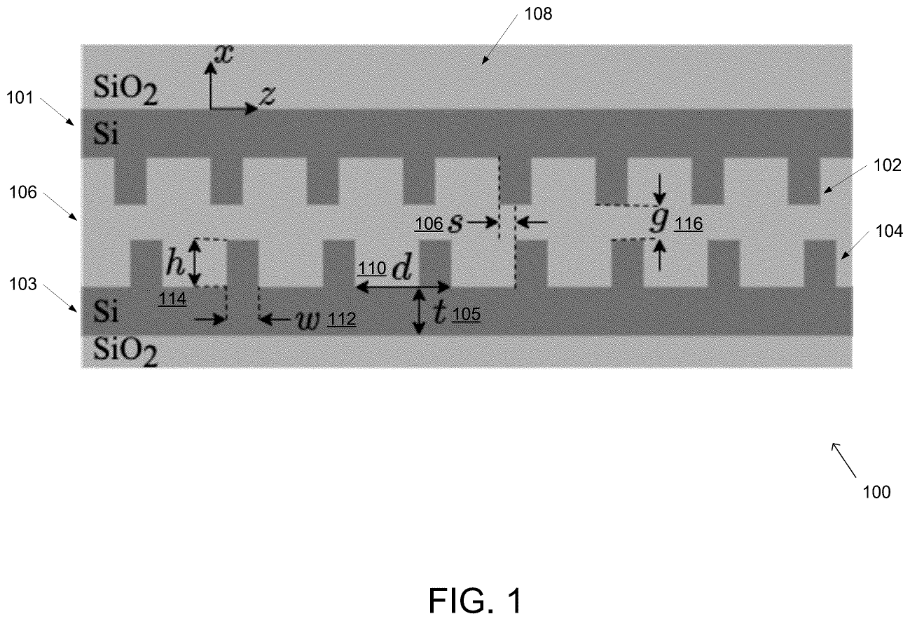

A diagram illustrating a DDFB photonic structure with double grating supporting guided longitudinal modes in the z direction in accordance with an embodiment of the invention is shown in FIG. 1. The DDFB photonic structure 100 may include a first waveguide 101 having first optical gratings 102 and a second waveguide 103 having second optical gratings 104. In many embodiments, the first and second optical gratings 102, 104 may be oppositely-facing and form a double grating, as further described below. The first and second optical gratings 102, 104 may be shifted by a distance s 106 (may also be referred to as a “translation s”) along z to enable the occurrence of the very flat band in the dispersion diagram provided by Eq. 2 below.

In reference to FIG. 1, the DDFB photonic structure 100 described herein may feature a double grating configuration. In some embodiments, the double grating configuration may include a standard grating that is coupled with another grating obtained after performing a mirror operation in the x direction and a translation s 106 in the z direction. The waves in each optical grating couple with the waves in the other grating, forming a double grating structure that supports four modes that may coalesce at the DBE (including the evanescent ones). The longitudinal translation s 106 breaks mirror symmetry, which would otherwise prevent the formation of a four-wave degeneracy in two periodic coupled waveguides. In many embodiments, the first and second optical gratings 102, 104 (may be referred to collectively as “double grating”) may be based on silicon-on-insulator (SOI) technology. However, in some embodiments, the double grating 102, 104 may be built using various materials including, but not limited to, SiN, InP, LiNbO₃, GaAs, InGaAsP, AlGaAs, etc.

In reference to FIG. 1, the first and second waveguides 101, 103 may have a thickness t 105, gratings (i.e., first and second optical gratings 102, 104, respectively) may have a period d 110, width w 112, and a height h 114. In addition, double gratings 102, 104 may have a coupling gap g 116. In many embodiments, the coupling gap g 116 and the shift between the waveguides (e.g. translation s) 106 may be optimized to achieve a DBE, as further described below.

The DDFB mechanism may be established in multimode systems made of various two or more parallel ridge waveguides coupled with each other. As used herein, the term “DDFB geometries” may refer to the geometries of the DBE-supporting waveguides that are described herein.

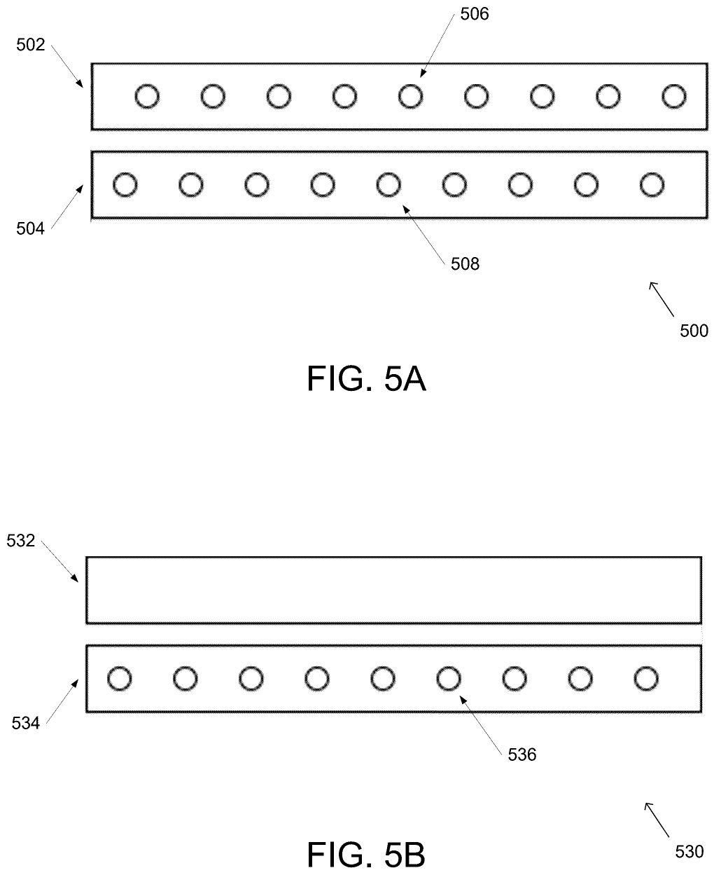

Diagrams illustrating DDFB geometries with holes in accordance with an embodiment of the invention are shown in FIGS. 5A-B. In reference to FIG. 5A, the DDFB geometry 500 may include a first waveguide 502 and a second waveguide 504. In many embodiments, the first and second waveguides 502, 504 may be straight. In some embodiments, the first and second waveguides 502, 504 may be parallel. The first waveguide 502 may include first holes 506. In some embodiments, the first holes 506 may be equally sized. In some embodiments, the first holes 506 may be separated by an equal spacing distance. Further, the second waveguide 504 may include second holes 508. In some embodiments, the second holes 508 may be equally sized. In some embodiments, the second holes 508 may be separated by an equal spacing distance. In addition, in some embodiments, the first holes 506 and the second holes 508 may be equally sized. In some embodiments, the first holes 506 and the second holes 508 may be offset relative to each other. In reference to FIG. 5B, the DDFB geometry 530 may include a first waveguide 532 and a second waveguide 534 where only one of the two waveguides includes holes. In some embodiments, the first and second waveguides 532, 534 may be straight. The first and second waveguides 532, 534 may be parallel to each other. In some embodiments, the first waveguide 532 may not include holes and the second waveguide 534 may include second holes 536. In some embodiments, the second holes 536 may be equally sized. In some embodiments, the second holes 536 may be separated by an equal spacing distance.

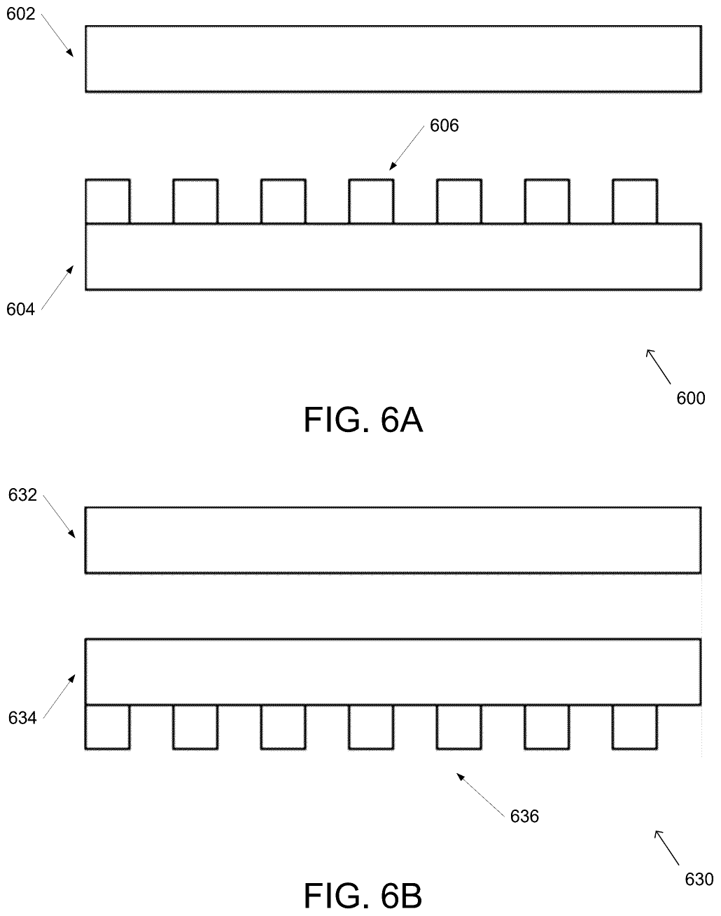

Diagrams illustrating DDFB geometries with a single grating in accordance with an embodiment of the invention are shown in FIGS. 6A-B. In reference to FIG. 6A, the DDFB geometry 600 may include a first waveguide 602 and a second waveguide 604 where only one of the two waveguides includes gratings and some waveguide may be multimode. In some embodiments, the first and second waveguides 602, 604 may be straight. In some embodiments, the first and second waveguides 602, 604 may be parallel to each other. In some embodiments, the first waveguide 602 may not include gratings but the second waveguide 604 may include gratings 606. In some embodiments, the gratings 606 may be equally sized rectangular gratings. In some embodiments, the gratings 606 may be separated by an equal spacing distance. The gratings 606 may be positioned on the second waveguide 604 between the first and second waveguides 602, 604. In reference to FIG. 6B, the DDFB geometry 630 may include a first waveguide 632 and a second waveguide 634 where only one of the two waveguides includes gratings. In some embodiments, the first and second waveguides 632, 634 may be straight. In some embodiments, the first and second waveguides 632, 634 may be parallel to each other. In some embodiments, the first waveguide 632 may not include gratings but the second waveguide 634 may include gratings 636. In some embodiments, the gratings 636 may be equally sized rectangular gratings. In some embodiments, the gratings 636 may be separated by an equal spacing distance. The gratings 636 may be positioned on the second waveguide 634 facing away from the first and second waveguides 632, 634.

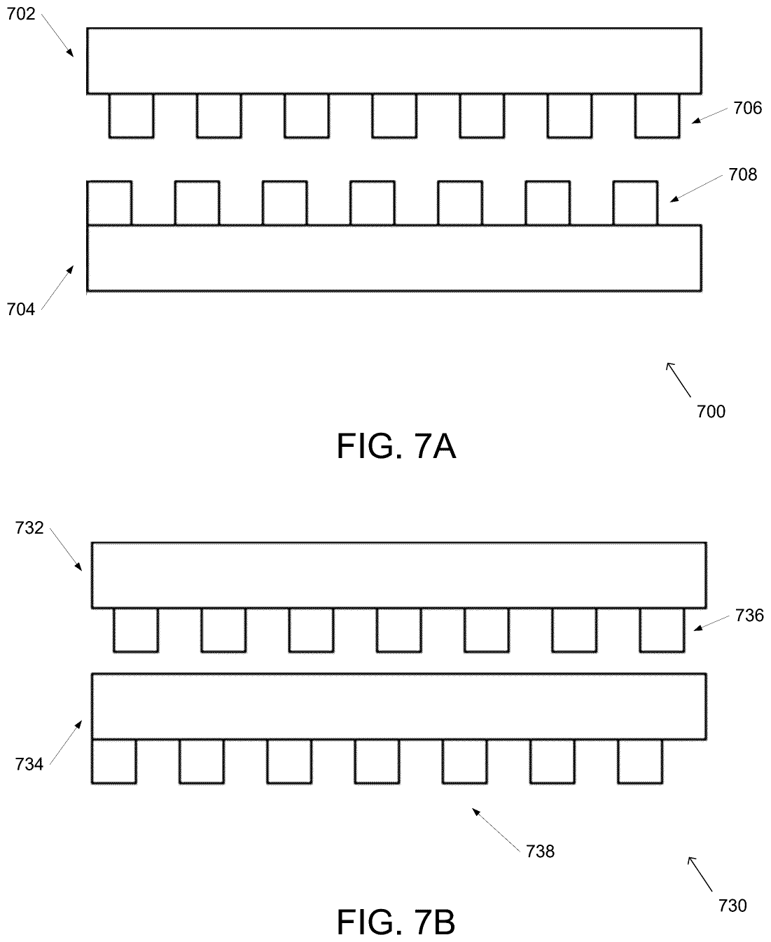

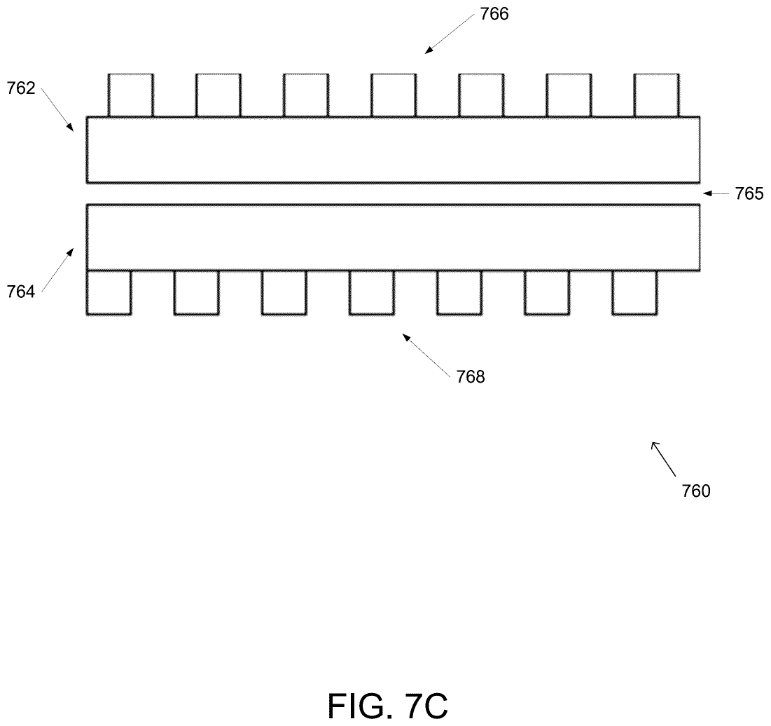

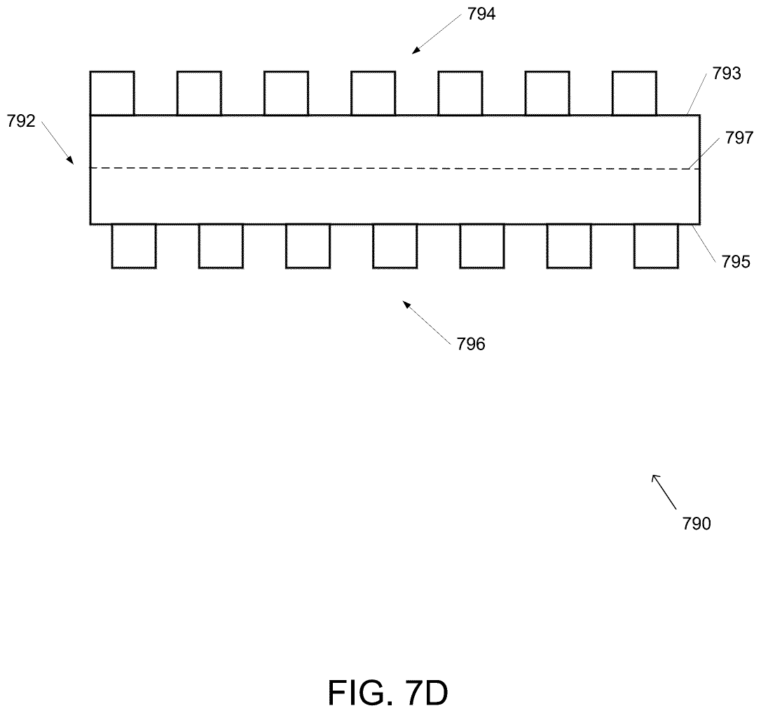

Diagrams illustrating DDFB geometries with double gratings in accordance with an embodiment of the invention are shown in FIGS. 7A-D. In reference to FIG. 7A, the DDFB geometry 700 may include a first waveguide 702 and a second waveguide 704. In some embodiments, the first and second waveguides 702, 704 may be straight. In some embodiments, the first and second waveguides 702, 704 may be parallel to each other. The first waveguide 702 may include first optical gratings 706. In some embodiments, the first optical gratings 706 may be equally sized rectangular gratings. In some embodiments, the first optical gratings 706 may be separated by an equal spacing distance. The second waveguide 704 may include second optical gratings 708. In some embodiments, the second optical gratings 708 may be equally sized rectangular gratings. In some embodiments, the second optical gratings 708 may be separated by an equal spacing distance. In some embodiments the period of the two gratings may not be the same. The first and second optical gratings 706, 708 may be positioned between the first and second waveguides 702, 704. In some embodiments, the first and second optical gratings 706, 708 may be offset relative to each other (e.g., shifted by a translation s as further described above). In reference to FIG. 7B, the DDFB geometry 730 may include a first waveguide 732 and a second waveguide 734. In some embodiments, the first and second waveguides 732, 734 may be straight. In some embodiments, the first and second waveguides 732, 734 may be parallel to each other. The first waveguide 732 may include first optical gratings 736. In some embodiments, the first optical gratings 736 may be equally sized rectangular gratings. In some embodiments, the first optical gratings 736 may be separated by an equal spacing distance. The second waveguide 734 may include second optical gratings 738. In some embodiments, the second optical gratings 738 may be equally sized rectangular gratings. In some embodiments, the second optical gratings 738 may be separated by an equal spacing distance. The first and second optical gratings 736, 738 may be facing the same direction. In some embodiments, the first and second optical gratings 736, 738 may be offset relative to each other. In reference to FIG. 7C, the DDFB geometry 760 may include a first waveguide 762 and a second waveguide 764. In some embodiments, the first and second waveguides 762, 764 may be straight. In some embodiments, the first and second waveguides 762, 764 may be parallel to each other. The first waveguide 762 may include first optical gratings 766. In some embodiments, the first optical gratings 766 may be equally sized rectangular gratings. In some embodiments, the first optical gratings 766 may be separated by an equal spacing distance. The second waveguide 764 may include second optical gratings 768. In some embodiments, the second optical gratings 768 may be equally sized rectangular gratings. In some embodiments, the second optical gratings 768 may be separated by an equal spacing distance. The first and second optical gratings 766, 768 may be facing away from a center 765 located between the first and second waveguides 762, 764. In some embodiments, the first and second optical gratings 766, 768 may be offset relative to each other. In reference FIG. 7D, the DDFB geometry 790 includes a single multimode waveguide 792. In some embodiments, the waveguide 792 may be straight. The waveguide 792 may include a plurality of optical gratings 794 located on a first side 793 of the waveguide 792 and a plurality of optical gratings 796 located on a second side 795 of the waveguide 792. In some embodiments, the optical gratings 794 located on the first side 793 of the waveguide 792 may be equally sized rectangular gratings. In some embodiments, the optical gratings 794 located on the first side 793 of the waveguide 792 may be separated by an equal spacing distance. In some embodiments, the optical gratings 796 located on the second side 795 of the waveguide 792 may be equally sized rectangular gratings. In some embodiments, the optical gratings 796 located on the second side 795 of the waveguide 792 may be separated by an equal spacing distance. In various embodiments, the optical gratings 794, 796 may be facing away from an imaginary center line 797 of the waveguide 792. In some embodiments, the optical gratings 794 located on the first side 793 and the optical gratings 796 located on the second side 795 of the waveguide 792 may be offset relative to each other. For example, the plurality of optical gratings 794 located on the first side 793 and the plurality of optical gratings 796 located on the second side 795 may be shifted by a translation s.

In addition, even a multimode single ridge waveguide with proper mode mixing due to periodic perturbations can also support a DDFB mechanism. The key aspect is to couple at least two optical waveguides in a distributed manner to provide enough distributed feedback to form a DBE. If the DDFB mechanism is constricted using only two coupled optical waveguides supporting a mode each, the overall structure must have broken mirror symmetry to exhibit the DBE, by using a simple longitudinal shift or even by having two waveguides with different dimensions.

In further reference to FIG. 1, we show an example of a double grating waveguide with a silicon core 106, with a refractive index of nₛ_{ᵢ}=3.45, and a silicon dioxide cladding 108, with a refractive index of nₛᵢₒ_{₂}=1.44. For simplicity, we assume the materials do not exhibit dispersive behavior in the frequency range of interest (around f=193.6 THz).

The optical modes in the DDFB waveguide are here modeled using a full-wave electromagnetic field solver like CST Studio Suite that uses the finite element method (FEM). Our objective is to obtain longitudinal modes that propagate in the z direction and are polarized in the y direction, following the coordinate system shown in FIG. 1. In this case we use the geometry where the two gratings are on top of each other, i.e., stacked in the x direction, but analogous results can be obtained for two waveguides with gratings next to each other. To reduce the computational cost, we may perform quasi 2D simulations, where the dimension l of the waveguide in the y direction is less than the wavelength with two walls of perfect electric conductor (PEC) boundary conditions. This is equivalent to imposing that only the electric field polarized along y propagates.

The modal dispersion relation of the longitudinal modes in the infinitely-long double grating structure may be obtained by modeling one unit cell of the waveguide in the eigenmode solver of CST Studio Suite. For modeling purposes, we may use two PEC walls in the y-z plane, at the top and bottom of the cladding at two x coordinates, which are far enough from the double grating so as to not interfere with its longitudinal modes.

Although specific DDFB photonic structures including waveguides with double gratings, single gratings, and holes are discussed above with respect to FIGS. 1 and 5A-7D, any of a variety of DDFB photonic structures as appropriate to the requirements of a specific application can be utilized in accordance with embodiments of the invention. Further, the various parameters discussed in FIG. 1 (e.g., thickness t, period d, width w, height h, coupling gap g, translation s, etc.) may be used to described the various DDFB geometries described in FIGS. 5A-7D. DBE in DDFB is discussed further below.

### DBE in DDFB

DDFB double gratings exhibit a four-mode coalescence at the degeneracy angular frequency ω_{D}. A dispersion diagram of the longitudinal modes in a DDFB double grating optimized to exhibit a DBE in accordance with an embodiment of the invention is shown in FIG. 2. In the dispersion diagram 200, only the branches with purely real wavenumbers are shown, i.e., the branches with a complex-valued wavenumber are not shown. The purely-real-wavenumber branch shows that two modes coalesce at the DBE frequency f_{D} is depicted in curve 202. The evanescent modes (with complex-valued wavenumber) coalescing at the middle of the flat band edge are not shown in the figure. The branch showing the regular band edge (RBE) at f_{R} is depicted in curve 204. The flatness 203 associated to the DBE (see Eq. 2) is noticeably greater than the flatness 205 associated to the RBE.

FIG. 2 shows the modal dispersion diagram 200 of modes in a DDFB double grating with the following parameters (in μm): t=0.08, s=0.125, d=0.33, h=0.1, g=0.2, and w=0.09. The curve 202 denotes the two propagating modes that coalesce at the DBE frequency f_{D}=193.6 THz (the evanescent modes there coalescing are not shown for simplicity). Reciprocity leads to the formation of the DBE at the edge of the Brillouin zone (BZ), i.e., at kd/π=1. The curve 204 at lower frequencies denotes the two propagating modes that coalesce forming a RBE that occurs in the same double grating structure. The RBE is a second-order degeneracy only involving the coalescence of the two counter-propagating modes in the waveguide, which form a standing wave. Typically, a DFB laser operates in the vicinity of an RBE, whereas the DDFB operates in close proximity to a DBE. Near an RBE angular frequency ω_{R}=2πf_{R}, the dispersion diagram can be approximated as

$$( ω - {ω}_{R} ) ∝ {( k - {k}_{R} )}^{2} , \qquad ( 1 )$$

while at frequencies near the DBE, the dispersion diagram is approximated as

$$( ω - {ω}_{D} ) ∝ {( k - {k}_{D} )}^{4} , \qquad ( 2 )$$

where k_{R} and k_{D} are the wavenumbers at the DBE and the RBE, respectively. The reason for the flatter modal dispersion around the DBE frequency compared to the RBE frequency in FIG. 2 is because the flatness at the RBE frequency is only due to the coalescence of two modes, while the flatness at the DBE frequency is due to the coalescence of four modes. This four-wave degeneracy exhibits comparatively larger field amplitude enhancement and group delay than the RBE-associated slow wave resonance. As a result, waveguides operating near the DBE often demonstrate an enhanced performance compared to those operating near an RBE. For instance, the quality factor associated with the RBE increases asymptotically with the waveguide length as Q_{R}∝N³, whereas the quality factor associated with the DBE scales asymptotically as Q_{D}∝N⁵, where N is the number of unit cells.

The properties of a finite-length DDFB may be obtained using the frequency domain solver in CST Studio Suite. The finite-length DDFB includes N unit cells of the double grating, each with a period d=330 μm, as illustrated in FIG. 1. The first and last unit cells are terminated with a 400 μm straight slab waveguide segments. These dielectric slab waveguides (some of them or even all of them) are continued with single modes straight slab waveguides. This forms a cavity even without any mirrors or discontinuity. For this cavity to display the properties associated with the DBE, a resonance should occur in proximity to the DBE frequency. We call the resonance closest to the DBE the “DBE resonance”, occurring at @Dr.

There may be two methods to calculate the quality factor of the DDFB photonic cavity at the DBE resonance ψ_{D,r}. The first approach may start by determining the group delay τ_{g} of the waveguide by taking the negative of the derivative of the phase of the S₂₁ transmission parameter (we use the time-harmonic convention e^{jωt}) with respect to the angular frequency, i.e.,

$${τ}_{g} ( ω ) = - \frac{\partial ∠ {S}_{21}}{\partial ω} . \qquad ( 3 )$$

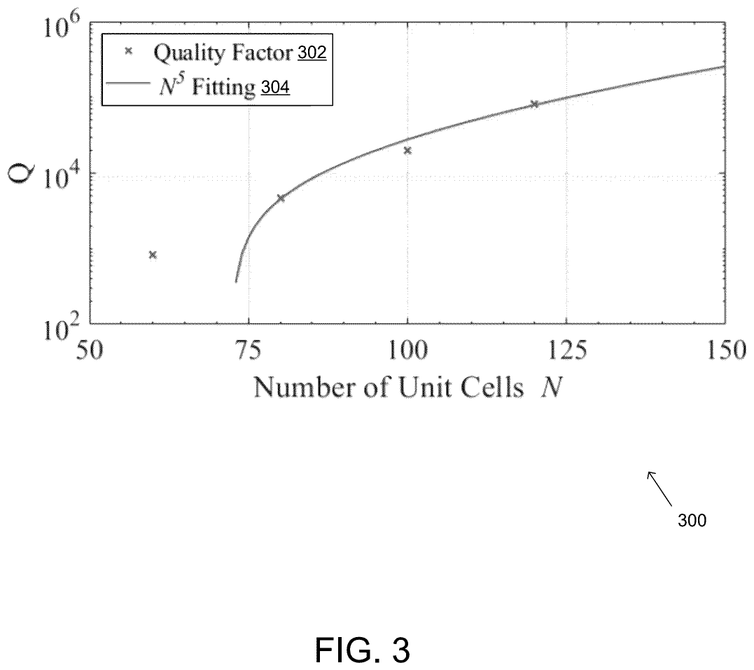

The quality factor Q at the resonance angular frequency ω_{D,r} for periodic waveguides of large N is then reliably approximated as

$$Q = \frac{1}{2} {ω}_{D , r} {τ}_{g} ( {ω}_{D , r} ) . \qquad ( 4 )$$

where the group delay is evaluated at the same resonance ω_{D,r}. The quality factor is also calculated as

$$Q = \frac{{ω}_{D , r}}{Δω} , \qquad ( 5 )$$

where Δω is the 3 dB bandwidth around the resonance frequency of interest. We have calculated the quality factor at the DBE resonance frequency using both methods to ensure the validity of the results. A diagram illustrating a quality factor and its fitting N⁵ scaling law of the DDFB double grating versus number of unit cells N in accordance with an embodiment of the invention is shown in FIG. 3. Diagram 300 illustrates the DBE quality factor 302 of the double grating with different numbers of unit cells N, evaluated using Eq. (5) (using Eq. (4) instead leads to the same result). The line 304 represents the fitting trend Q_{E}≈aN⁵+b for the DBE, where a=3.45×10⁻⁶ and b=−6.8×10³.

The present embodiments showcase the enhanced group delay in the DDFB double grating due to the four-wave degeneracy by comparing the group delay of a DDFB waveguide of N=120 cells at a frequency of 193.6 THz, τ_{g}=826.28 ps, with that of a straight waveguide with the same modal refractive index n_{eff}=2.05 and an identical length of 40.2 microns, resulting in τ_{g}=0.28 ps. The waves propagating in a DDFB waveguide with N=120 unit cells experience almost 3000 times as much group delay as they would in a straight waveguide with the same modal refractive index and length. This result and the fifth power scaling of the quality factor with the double grating length shown in FIG. 3 confirm that the DDFB double grating experiences a DBE at f_{D}=193.6 THz.

Although specific DBE considerations and results for DDFB are discussed above with respect to FIGS. 2-3, any of a variety of DBE considerations and results for DDFB as appropriate to the requirements of a specific application can be utilized in accordance with embodiments of the invention. DDFB-induced lasing is discussed further below.

### DDFB-Induced Lasing

In many embodiments, there may be various ways to include gain in an active medium. For example, as further described below, gain may be uniformly distributed in the oxide cladding. Because of the uniformity, the gain can be modeled by an imaginary component of the cladding refractive index. In particular, gain is the imaginary part n″, of a complex refractive index, i.e., n=n_{b}−jₙ″_{g}, where ng is the bulk (cladding) refractive index. The e^{jωt} time convention is implicitly used. As an example reported here, the gain region may include the cladding between the gratings, which increases the interaction between the waves and the gain medium. Other embodiments of this invention may use gain inside the waveguide or in a single layer next to the waveguides.

In many embodiments, a gain coefficient α_{g} (in units of dB/cm) can be defined as the power amplification over a centimeter length. This is an equivalent representation to the imaginary refractive index and the gain in terms of the imaginary part of a refractive index at an angular frequency ω is approximated by n″_{g}(ω)≈α_{g}(100/8.686)(c₀/ω) where c₀ is the speed of light in vacuum. The imaginary part of the bulk refractive index is negative for gain, i.e., n″_{g}<0. The imaginary part of the cladding complex permittivity is then ε″_{g}=2n_{b}n″_{g}. The present embodiments may include various ways to amplify the signal in the waveguide, or otherwise include gain in the device. For example, electrical pumping, otherwise known as current injection, is a common and practical way to include gain. Current injection can be facilitated through a semiconductor active layer embedded or integrated in an otherwise passive material configuration, or applied after a photonic chip is fabricated. Current injection is also possible with a quantum well configuration using a doped semiconductor stack or similar implementation.

Another method to add gain to an optical cavity may include optical pumping. Generally, optical pumping may involve doping the device's material with ions of a different material. For example, the silicon oxide cladding in the DDFB double grating could be doped with various materials such as, but not limited to, Erbium or Yttrium ions. A shorter-wavelength pump source would then be applied to the device for amplification at the operating, longer, wavelength. The optical source could also be a broadband source rather than another laser. In several embodiments, lasing threshold may be defined where the lasing threshold aₜₕ represents the minimum amount of gain necessary for an active DDFB to start oscillating. In other words, the value of α_{g} that is the lasing threshold is given by aₜₕ. Since the DBE quality factor scales as Q_{D}∝N⁵ for increasingly large N and that typically aₜₕ∝1/Q, we anticipate the lasing threshold in the DDFB double grating exhibits asymptotic scaling with waveguide length such that aₜₕ∝N⁻⁵.

To determine the lasing threshold of finite-length DDFB, we gradually increase the gain while monitoring when the structure shows an unstable behavior. This is done by tracking the poles of the S₂₁ transmission parameter at the DBE resonance. To account for the shift in the DBE resonance frequency as the gain increases, S₂₁ may be evaluated in a narrow frequency range around the DBE resonance angular frequency w_{D,r}±δ for varying α_{g}, where the value of δ depends on the length of the DDFB double grating.

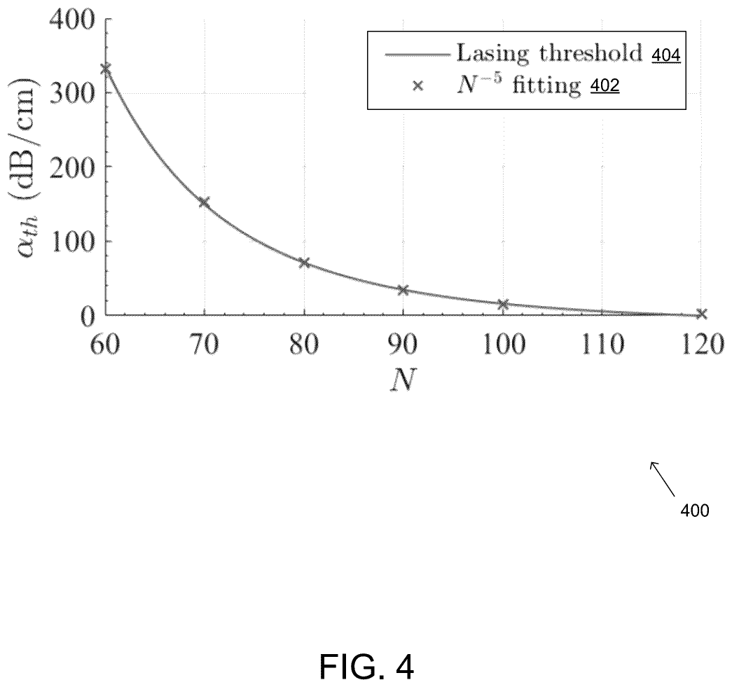

A diagram illustrating a lasing threshold aₜₕ and its fitting N⁻⁵ scaling law of the DDFB double grating versus number of unit cells N in accordance with an embodiment of the invention is shown in FIG. 4. Finite-length DDFB double gratings of N=60, 70, 80, 90, 100, 120 unit cells have a lasing threshold of aₜₕ=332.5, 153.5, 70.5, 33.5, 15, 3 dB/cm. These values are denoted by crosses 402 in FIG. 4. The continuous line 404 represents the aₜₕ=2.7×10¹¹N⁻⁵−11 fitting curve. These results were obtained using the finite-length double grating structure described above, and without mirrors. In fact, preliminary results show that when considering a DDFB cavity made of 70 or 80 unit cells, varying the 400 μm straight waveguide segments on both ends of the structure by ±50 μm results in a variation of 0.5 dB/cm in the lasing threshold. The DDFB double grating exhibits very small lasing thresholds.

The main implication of this anomalous lasing threshold trend with cavity length represents a trade-off between the DDFB laser length and the amount of gain required to operate it. However, this anomalous scaling law and that of the quality factor Q may be bounded by the presence of defects, losses, and fabrication tolerances.

Additionally, incorporating mirrors to the cavity model would increase the available degrees of freedom for threshold minimization and lasing stability. Further, the results illustrated in FIG. 4 may represent a condition of negligible losses. When losses are present, the results may deviate, for large N.

Although specific DDFB-induced lasing considerations and results are discussed above with respect to FIG. 4, any of a variety of DDFB-induced lasing considerations and results as appropriate to the requirements of a specific application can be utilized in accordance with embodiments of the invention. Distortion of the DBE dispersion diagrams are discussed further below.

### Distortion of the DBE Dispersion Diagrams Due to Gain and Tolerances

In various embodiments, devices operating near an EPD display a well-established exceptional sensitivity to parameter perturbations. Looking at the modal wavenumber dispersion diagram, for the case of a DBE device with gain, the degenerate wavenumber k_{D} splits into four wavenumbers k_{q}, with q=1, 2, 3, 4, as a consequence of the change Δn in the refractive index due to gain or other external factors like losses or fabrication tolerances. The perturbed wavenumbers may be estimated by the Puiseux fractional series truncated to its first term as

$${k}_{q} ( Δ n ) \approx {k}_{D} + β {e}^{j \frac{π}{2} q} \sqrt[4]{Δ n} , \qquad ( 6 )$$

The coefficient β may be calculated. The wavenumber perturbation is therefore much stronger near the DBE frequency than at frequencies far away from it, where the perturbation generally follows the linear relationship typical of a Taylor expansion. While this feature is attractive for signal modulation, it could thwart the formation of the degenerate mode, therefore preventing the display of its exceptional properties. However, the optical modes near the DBE frequency are still expected to exhibit a certain coalescence for small values of gain, and therefore the active DDFB double grating retains the features uniquely associated with the DBE. For larger values of gain, however, the distortion may be large enough to prevent the formation of the four-mode degeneracy.

The preservation of the DBE in the DDFB double grating with gain is apparent in FIG. 4. These results show that for devices with a large number of unit cells N, the gain required to obtain oscillation is very small and decreases as N⁻⁵. Therefore, for finite-length DDFB devices, the gain may be small enough so that the properties of the four-mode degeneracy are expected to be maintained. Exemplary DDFB laser devices are discussed further below.

### Exemplary DDFB Laser Devices

As further described above, DDFB lasers may be based on having four degenerate modes in the longitudinal grating (i.e., a grating structure along the direction of propagation of the guided waves). In many embodiments, to have four degenerate modes, instead of an optical grating, the present embodiments utilize two closely coupled optical gratings in various confirmations. For example, in some embodiments, the gratings may be next to each other. In other examples, the gratins may be one on top of the other. In various embodiments, the waves in each optical gratings couple with the waves in the other grating, forming a double grating structure that supports four modes, either propagating or evanescent. In several embodiments, the optical gratings may be designed to have a degeneracy between these four optical modes, providing a stronger feedback and frequency selective mechanism than embodiments relying only on two modes. In addition, gain may be included in the cavity in various ways, as further described herein. In some embodiments, the degenerate mode is the mode that will generate laser oscillations. The high frequency selectivity of the DDFB lasing mode and its low spectral noise make the DDFB laser very attractive for various applications where the spectral purity is important, like in long range spectral communications, high bit rate modulations, sensing, spectroscopy, etc.

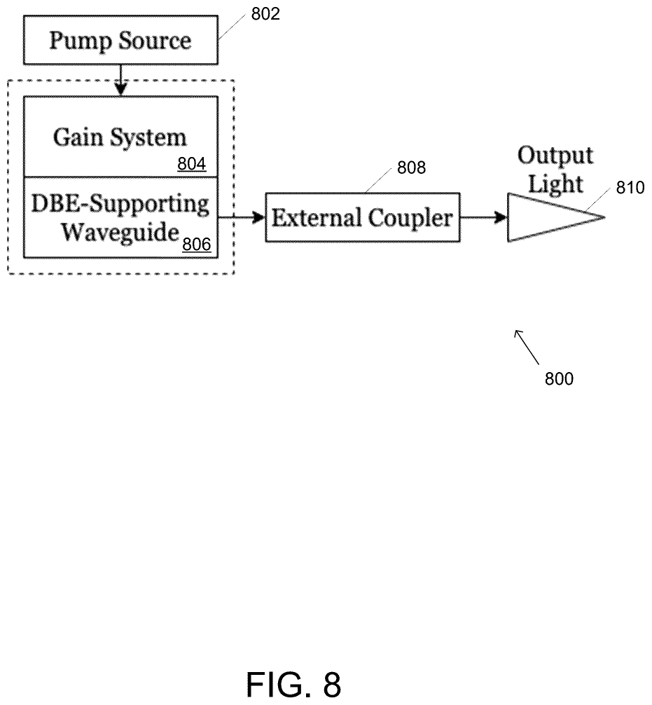

A block diagram illustrating an example DDFB laser in accordance with an embodiment of the invention is shown in FIG. 8. The DDFB laser 800 may include a pump source 802 operative connected to a gain system 804. In many embodiments, the pump source 802 may supply power to the gain system 804. The DDFB laser 800 also includes DBE-supporting waveguide(s) 806, as further described herein. The gain system 804 may directly interact with the DBE-supporting waveguide 806 to provide stimulated emission and amplification for lasing. In various embodiments, the DBE-supporting waveguide(s) 806 may be operatively connected to a coupler such as, but not limited to, an external coupler 808 to collect and focus the laser beam. In several embodiments, the external coupler 808 may facilitate the output of light 810, either vertically from the grating itself or from a waveguide end.

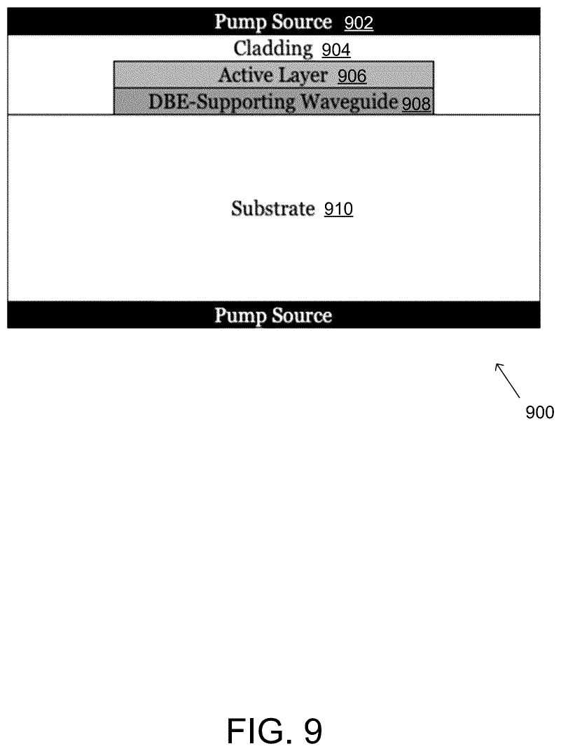

In some embodiments, the DDFB laser may include a DDFB semiconductor stack. A block diagram illustrating an example DDFB stack with an active layer adjacent to a DBE-supporting waveguide in accordance with an embodiment of the invention is shown in FIG. 9. The DDFB semiconductor stack 900 may include an active layer 906 and a DBE-supporting waveguide 908. In some embodiments, the active layer 906 and the DBE-supporting waveguide 908 may be surrounded by cladding 904 and/or substrate 910. In some embodiments, the cladding 904 and/or substrate 910 may have dopant material added. The DDFB semiconductor stack 900 may also include a pump source 902. The pump source 902 may be electrical or optical. In some embodiments, the pump source 902 may be placed around the waveguiding structure.

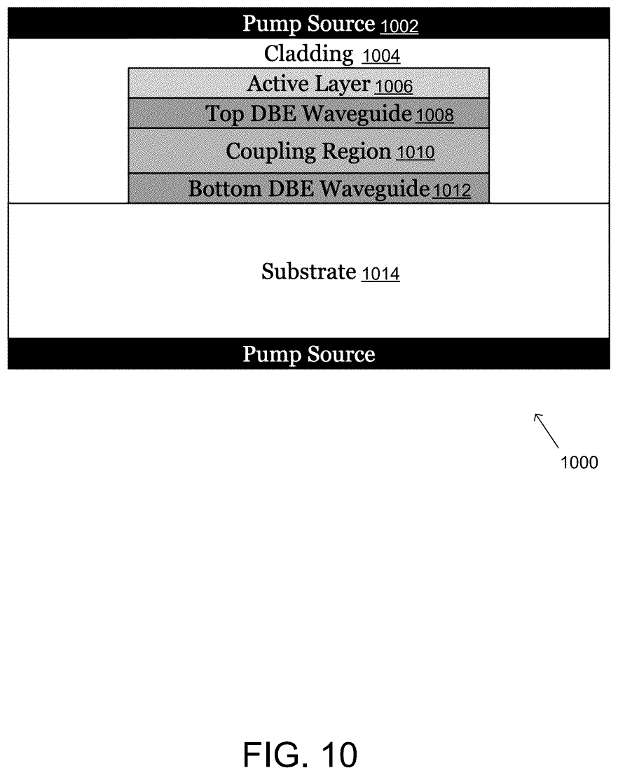

As further described above, DBE-supporting waveguides may include various DDFB geometries. A block diagram illustrating an example DDFB stack with an active layer and DBE-supporting waveguide having two gratings on top of each other in accordance with an embodiment of the invention is shown in FIG. 10. The DDFB semiconductor stack 1000 may include an active layer 1006 and a DBE-supporting waveguide comprising a top DBE waveguide 1008 and a bottom DBE waveguide 1012. In many embodiments, the top and bottom DBE waveguides 1008, 1012 may be positioned on top of each other and may provide for a coupling region 1010 between the top and bottom DBE waveguides 1008, 1012. For example, the coupling region 1010 may define a region that includes first optical gratings (of the top DBE waveguide 1008) and second optical gratings (of the bottom DBE waveguide 1012). In various embodiments, the first and second optical gratings may be configured as various DDFB geometries with double gratings, as further described above. Moreover, the active layer 1006 and the DBE-supporting waveguide (i.e., the top DBE waveguide 1008, grating region 1010, and bottom DBE waveguide 1012) may be surrounded by cladding 1004 and/or substrate 1014. The DDFB semiconductor stack 1000 may also include a pump source 1002. The pump source 1002 may be electrical or optical. In some embodiments, the pump source 1002 may be placed around the waveguiding structure.

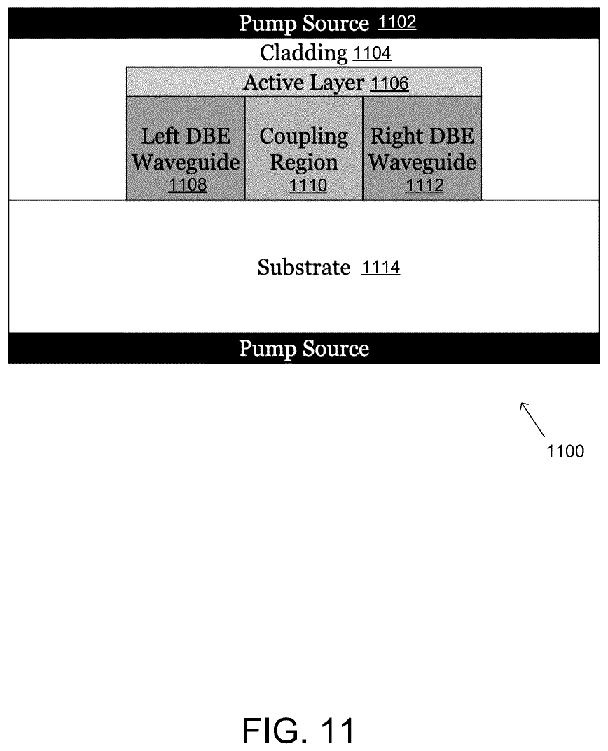

A block diagram illustrating an DDFB stack with an active layer and DBE-supporting waveguide having two gratings next to each other in accordance with an embodiment of the invention is shown in FIG. 11. The DDFB semiconductor stack 1100 may include an active layer 1106 and a DBE-supporting waveguide comprising a left DBE waveguide 1108 and a right DBE waveguide 1112. In many embodiments, the left and right DBE waveguides 1108, 1112 may be positioned next to each other and may provide for a coupling region 1110 between the left and right DBE waveguides 1108, 1112. For example, the coupling region 1110 may define a region that includes first optical gratings (of the left DBE waveguide 1108) and second optical gratings (of the right DBE waveguide 1112). In various embodiments, the first and second optical gratings may be configured as various DDFB geometries with double gratings, as further described above. In addition, the active layer 1106 and the DBE-supporting waveguide (i.e., the left DBE waveguide 1108, grating region 1110, and right DBE waveguide 1112) may be surrounded by cladding 1104 and/or substrate 1114. The DDFB semiconductor stack 1100 may also include a pump source 1102. The pump source 1102 may be electrical or optical. In some embodiments, the pump source 1102 may be placed around the waveguiding structure.

Although specific block diagrams of example DDFB lasers and DDFB stacks are discussed above with respect to FIGS. 8-11, any of a variety of DDFB lasers and DDFB stacks, including DDFB lasers and DDFB stacks with additional components, less components, substitute components, and/or variations to provided components, as appropriate to the requirements of a specific application may be utilized in accordance with embodiments of the invention. While the above description contains many specific embodiments of the invention, these should not be construed as limitations on the scope of the invention, but rather as an example of one embodiment thereof. It is therefore to be understood that the present invention may be practiced otherwise than specifically described, without departing from the scope and spirit of the present invention. Thus, embodiments of the present invention should be considered in all respects as illustrative and not restrictive.

What is claimed is:

1. A degenerate distributed feedback (DDFB) laser, the DDFB laser comprising:
a pump source operatively connected to a gain system, wherein the pump source provides power to a gain system;
the gain system operatively connected to at least one DBE-supporting waveguide, wherein the gain system stimulates emission and amplification for lasing;
at least one DBE-supporting waveguide that supports four degenerate modes and a degenerated feedback; and
a coupler operatively connected to the at least one DBE-supporting waveguide, wherein the coupler collects and focuses light from the DBE-supporting waveguide and outputs a laser beam.

2. The DDFB laser of claim 1 wherein the at least one DBE-supporting waveguide comprises a first waveguide and a second waveguide, wherein the first and second waveguides are coupled.

3. The DDFB laser of claim 2, wherein the first waveguide comprises a plurality of first optical gratings, and wherein each of the plurality of first optical gratings are separated by an equal distance.

4. The DDFB laser of claim 3, wherein the plurality of first optical gratings are equally sized rectangular gratings.

5. The DDFB laser of claim 4, wherein the second waveguide comprises a plurality of second optical gratings, and wherein each of the plurality of second optical gratings are separated by an equal distance.

6. The DDFB laser of claim 5, wherein the plurality of second optical gratings are equally sized rectangular gratings.

7. The DDFB laser of claim 6, wherein the plurality of first optical gratings and the plurality of second optical gratings are positioned between the first and second waveguides.

8. The DDFB laser of claim 7, wherein the plurality of first optical gratings and the plurality of second optical gratings are shifted by a translation s.

9. The DDFB laser of claim 6, wherein the plurality of first optical gratings and the plurality of second optical gratings are faced a same direction.

10. The DDFB laser of claim 9, wherein the plurality of first optical gratings and the plurality of second optical gratings are shifted by a translation s.

11. The DDFB laser of claim 6, wherein the plurality of first optical gratings and the plurality of second optical gratings are facing away from a center located between the first and second waveguides.

12. The DDFB laser of claim 11, wherein the plurality of first optical gratings and the plurality of second optical gratings are shifted by a translation s.

13. The DDFB laser of claim 2, wherein the second waveguide comprises a plurality of second optical gratings, and wherein each of the plurality of second optical gratings are separated by an equal distance.

14. The DDFB laser of claim 13, wherein the plurality of second optical gratings are equally sized rectangular gratings.

15. The DDFB laser of claim 4, wherein the plurality of second optical gratings are positioned between the first and second waveguides.

16. The DDFB laser of claim 4, wherein the plurality of second optical gratings are facing away from the first and second waveguides.

17. The DDFB laser of claim 2, wherein the first waveguide comprises a plurality of first holes, and wherein each of the plurality of first holes is equally sized and separated by an equal distance.

18. The DDFB laser of claim 17, wherein the second waveguide comprises a plurality of holes, and wherein each of the plurality of second holes is equally sized and separated by an equal distance.

19. The DDFB laser of claim 18, wherein the plurality of first holes and the plurality of second holes are shifted by a translation s.

20. The DDFB laser of claim 2, wherein the second waveguide comprises a plurality of holes and wherein each of the plurality of second holes is equally sized and separated by an equal distance.

21. The DDFB laser of claim 1, wherein the at least one DBE-supporting waveguide comprises a plurality of optical gratings located on a first side and a plurality of optical gratings located on a second side, and wherein:
the plurality of optical gratings located on the first side and the plurality of optical gratings located on the second side are facing away from a center of the DBE-supporting waveguide; and
the plurality of optical gratings located on the first side and the plurality of optical gratings located on the second side are shifted by a translation s.
